(19) United States
(12) Patent Application Publication
(10) Pub. No.: US 2024/0074052 A1
(43) Pub. Date: Feb. 29, 2024

(54) INTEGRATED SUBSTRATE AND POWER INTEGRATED CIRCUIT

(71) Applicant: Silergy Semiconductor Technology (Hangzhou) LTD, Hangzhou (CN)

(72) Inventors: Gao Fan, Hangzhou (CN); Yu Qi, Hangzhou (CN); Wei Chen, Hangzhou (CN)

(21) Appl. No.: 18/234,701

(22) Filed: Aug. 16, 2023

(30) Foreign Application Priority Data
Aug. 24, 2022 (CN) 202211016845.0

(51) Int. Cl. H05K 1/11; H01L 23/498

(52) U.S. Cl. CPC H05K 1/112; H01L 23/49822

(57) ABSTRACT

An integrated substrate can include: a top structure having a plurality of first pads for mounting electronic devices, where each of the first pads is electrically coupled with a corresponding electronic device, such that each of the first pads has a corresponding potential; a bottom structure having a plurality of second pads for coupling with peripheral circuits; a plurality of intermediate metal layers stacked up/down and located between the top structure and the bottom structure; a first type of penetrating connection structures configured to couple the intermediate metal layers and a part of the first pads, such that the intermediate metal layers have the same potential as the part of the first pads; and a second type of penetrating connection structures configured to couple the intermediate metal layers and the second pads, such that the second pads have the same potential as the part of the first pads.

### RELATED APPLICATIONS

This application claims the benefit of Chinese Patent Application No. 202211016845.0, filed on Aug. 24, 2022, which is incorporated herein by reference in its entirety.

### FIELD OF THE INVENTION

The present invention generally relates to the field of power electronics, and more particularly to integrated substrates and power integrated circuitry.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads.

### BRIEF DESCRIPTION OF THE DRAWINGS

FIG. 1 is a schematic circuit diagram of a first example power integrated circuit.

FIG. 2 is a schematic circuit diagram of a second example power integrated circuit.

FIG. 3 is a schematic circuit diagram of an example power integrated circuit, in accordance with embodiments of the present invention.

FIG. 4 is a schematic structural diagram of a first example integrated substrate, in accordance with embodiments of the present invention.

FIG. 5 is a schematic structural diagram of a second example integrated substrate, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

In a switching power supply, power transistors, filter capacitors, driving circuits and passive components are generally interconnected by a printed-circuit board (PCB). In a switching power supply module, the number of layers of the PCB may generally be determined by a planar magnetic element, and other electronic devices can be placed near the planar magnetic element. However, this placement approach may often need to set the connecting terminals in the planar magnetic element to connect with the switches, which may require a larger area of the PCB, and increased cost. In addition, because high-frequency current often flows through the planar magnetic element, a greater AC effect can be produced at the connecting terminals, which can cause a greater eddy current loss.

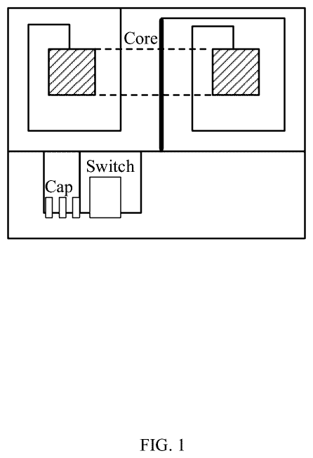

Referring now to FIG. 1, shown is a schematic circuit diagram of a first example power integrated circuit. In this example, the main power stage circuit is integrated in the power integrated circuit, in which the power transistors and its corresponding filter capacitors, as well as the driving circuit and passive components, are interconnected by a PCB. This example power integrated circuit may not only need a PCB with a relatively large area, but also the high-frequency current in the planar magnetic element may produce a relatively large AC effect in the connection terminal between the magnetic element and other electronic devices, which can cause a large eddy current loss.

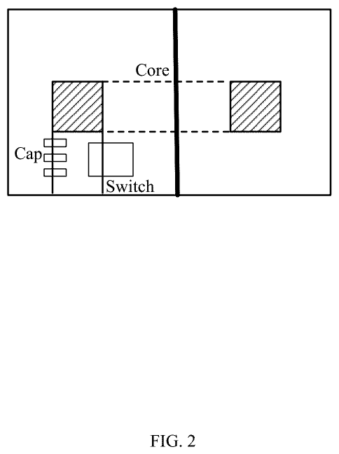

In order to reduce the eddy current loss, the main power stage circuit can be integrated in the power integrated circuit. Referring now to FIG. 2, shown is a schematic circuit diagram of a second example power integrated circuit. In this example, on the basis of the power integrated circuit shown in FIG. 1, the switching devices and filter capacitors in the main power stage circuit are directly placed above the planar magnetic element. The power integrated circuit shown in FIG. 2 reduces the length of the connection terminals, thereby reducing the eddy current loss. In addition, because the switching devices and the filter capacitors are placed directly above the winding of the planar magnetic element, the overall area of the power integrated circuit can be decreased.

However, for some more complex topologies, such as having more switching devices or filter capacitors or diodes besides magnetic elements, in order to achieve similar technical effects, it may be necessary to add more layers of PCB above the winding of the planar magnetic element. This is so that the switching devices can be connected to both ends of the filter capacitor while being connected to the magnetic element. Thus, a higher-order PCB may be needed, and the relationship between the cost of the high-order PCB and the cost of the low-order PCB is often nonlinear. For example, the price of 8-layer PCB is often more than twice that of 4-layer PCB. In order to reduce the loss and improve the circuit density, it may be necessary to design and simulate the structure of the connection terminals between the device pads and the corresponding parts of the main power stage circuit. However, there are many pads on the packaging structure of some devices with complex distribution, and different pads may need to be designed separately or cooperatively, particularly in high-frequency operating conditions. In addition, the wiring of the driving circuit may need to be refined. All of these factors can increase research and development time.

In order to solve such problems, particular embodiments may provide a power integrated circuit that can include a packaging module that packages the integrated substrate, switching devices, filter capacitors, and/or diodes together, whereby the packaging module has simple pads for connection to other (e.g., external) circuitry. In addition, because part of the electrical connection between electronic devices in a part of the main power stage circuit has been completed inside the integrated substrate, it may not be necessary to increase the number of PCB layers in the other parts of the main power stage circuit when the integrated substrate is connected with other parts of the main power stage circuit to form the power integrated circuit.

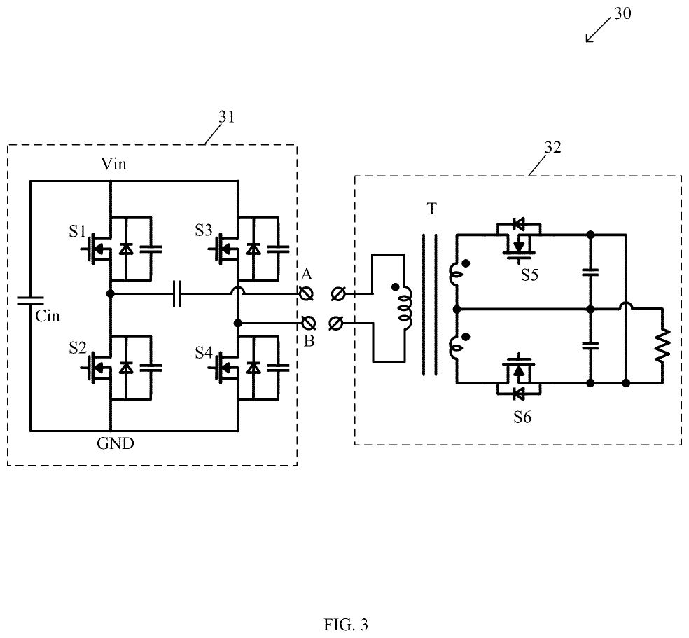

Referring now to FIG. 3, shown is a schematic circuit diagram of an example power integrated circuit, in accordance with embodiments of the present invention. The main power stage circuit of the power integrated circuit here is described by taking LLC topology as an example. In this particular example, power integrated circuit 30 can include at least two integrated circuit modules, which can respectively include some electronic devices in the main power stage circuit. For example, the LLC topology can include circuits 31 and 32. Circuit 31 can include input capacitor Cin and an inverter circuit including power switches S1 to S4. Circuit 32 can include a magnetic element (e.g., transformer T) and a post-rectification circuit including power switches S5 and S6. Circuit 31 can be distributed in one integrated circuit module, and circuit 32 can be distributed in another integrated circuit module. Two integrated circuit modules may be stacked up and down and connected with each other to form power integrated circuit 30. Further, at least one integrated circuit module can include an integrated substrate having first pads for soldering electronic devices, conductors for interconnecting the first pads, and second pads for connecting with external circuits.

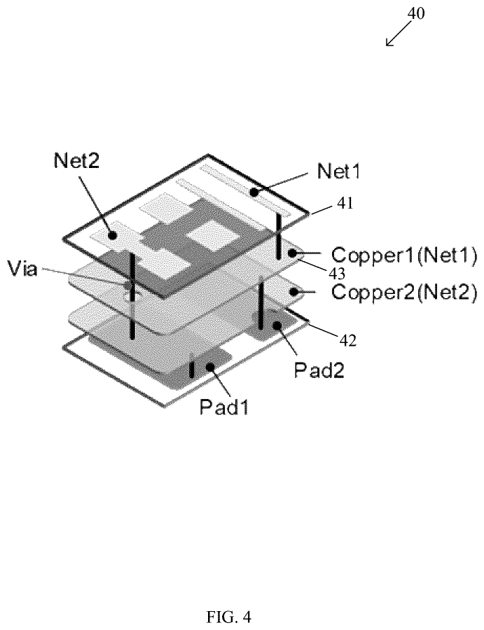

Referring now to FIG. 4, shown is a schematic structural diagram of a first example integrated substrate, in accordance with embodiments of the present invention. In this particular example, integrated substrate 40 can include top structure 41, bottom structure 42, a plurality of intermediate metal layers 43 stacked up and down and located between top structure 41 and bottom structure 42, and a plurality of types of penetrating connection structures.

Top structure 41 can include a plurality of first pads for mounting electronic devices. Each first pad can be electrically connected with a corresponding electronic device so that each first pad has a corresponding potential. Bottom structure 42 can include a plurality of second pads for connecting with peripheral circuits. The first type of penetrating connection structures can connect intermediate metal layer 43 and part of the first pads, such that intermediate metal layer 43 has the same potential as the part of the first pads. The second type of penetrating connection structures can connect intermediate metal layer 43 and the second pads, such that the second pads has the same potential as the part of the first pads. In addition, a plurality of different first pads can connect to a plurality of intermediate metal layers 43 through a plurality of the first type of penetrating connection structures, such that the potentials of intermediate metal layers 43 and the first pads are correspondingly equal. For example, a plurality of intermediate metal layers 43 may not be in the same plane, and different intermediate metal layers 43 can correspond to different potentials. Also, two adjacent intermediate metal layers 43 can at least partially overlapped.

Integrated substrate 40 may have two intermediate metal layers Copper1 and Copper2 as an example, but particular embodiments are not limited to this. Intermediate metal layer Copper1 can connect to first pad Net1 of top structure 41 through the first type of penetrating connection structure, and intermediate metal layer Copper2 can connect to first pad Net2 of top structure 41 through the first type of penetrating connection structure. Intermediate metal layer Copper1 can connect with second pad Pad2 of bottom structure 42 through the second type of penetrating connection structure, and intermediate metal layer Copper2 can connect with second pad Pad1 of bottom structure 42 through the second type of penetrating connection structure. Intermediate metal layers Copper1 and Copper2 can correspond to different potentials. Insulating materials may be filled between any adjacent two of top structure 41, bottom structure 42, and the plurality of intermediate metal layers 43. For example, the insulating materials can be PI, FR4, or ceramics.

At least one hole may be opened in at least one of top structure 41, bottom structure 42, and the plurality of intermediate metal layers 43 for avoiding one or more corresponding penetrating connection structures. For example, one penetrating connection structure, such as the first type of penetrating connection structure and the second type of penetrating connection structure, can connect any two of top structure 41, bottom structure 42, and the plurality of intermediate metal layers 43. In this example, a hole can be opened in each layer between the two of top structure 41, bottom structure 42, and the plurality of intermediate metal layers 43, in order to generate a conductor-free region for avoiding the penetrating connection structure. As such, the penetrating connection structure may not be connected with the each layer between the two of top structure 41, bottom structure 42, and the plurality of intermediate metal layers 43.

For example, first type of penetrating connection structure Via can connect intermediate metal layer Copper2 and top structure 41, and a hole may be opened in intermediate metal layer Copper1 between intermediate metal layer Copper2 and top structure 41, in order to avoid first type of penetrating connection structure Via. As such, first type of penetrating connection structure Via may not be connected with intermediate metal layer Copper1. In another example, in order to reduce costs, a hole can be opened in each layer except the two of top structure 41, bottom structure 42, and plurality of intermediate metal layers 43, in order to generate a conductor-free region for avoiding the penetrating connection structure. As such, the penetrating connection structure may not be connected with each layer except the two of top structure 41, bottom structure 42, and plurality of intermediate metal layers 43.

In this example, the first type of penetrating connection structure can connect top structure 41 and one of a plurality of intermediate metal layers, and the second type of penetrating connection structure can connect bottom structure 42 and one of the intermediate metal layers. For example, the first type of penetrating connection structure can connect the corresponding first pad on top structure 41 and one of the intermediate metal layers, and the second type of penetrating connection structure can connect the corresponding second pad on bottom structure 42 and one of the intermediate metal layers. For example, the distance between the edge of the hole and the penetrating connection structure can be greater than a predetermined threshold (e.g., 0.1 mil-1.0 mil, where a mil=inch/1000).

For example, two adjacent intermediate metal layers 43 can be at least partially overlapped, and the percentage of overlapping area between two adjacent intermediate metal layers in the area of each of two adjacent intermediate metal layers may exceed a preset value (e.g., 50%-100%). In example integrated substrate 40, the areas of intermediate metal layers Copper1 and Copper2 can be the same and completely overlapped, which may be beneficial to reducing the loop area of the integrated substrate. Further, the insulating medium between two adjacent intermediate metal layers can be, e.g., ceramics, polyimide, glass resin (e.g., FR4), and other materials. Minimizing the thickness of the insulating layer between two adjacent intermediate metal layers can be beneficial to the formation of a smaller AC loop area, thus further reducing the eddy current loss.

For example, according to the particular topology adopted by power integrated circuit 30, some electronic devices soldered on integrated substrate 40 can complete partially electrical connections inside integrated substrate 40 in advance. As such, integrated substrate 40 can connect with other integrated circuit modules only through second pads Pad1 and Pad2, thus forming a complete power integrated circuit. Further, intermediate metal layers Copper1 and Copper2, as well as the conductor for completing partial electrical connection inside integrated substrate 40, are not limited to metals such as copper, silver, gold, etc., as long as the resistivity is lower than a conference value (e.g., the resistivity of tin), in order to reduce the loss.

It should be noted that the capacitors soldered on integrated substrate 40 can be commercial capacitors, such as MLCC, electrolytic capacitor, CBB, tantalum capacitor, and so on. The capacitors can be directly made of conductors or intermediate metal layers and insulators in integrated substrate 40, and integrated substrate 40 may not have pads for soldering capacitors when such capacitors are used. The power switch soldered on integrated substrate 40 may not be limited to a single active element, such as MOSFET, IGBT, GTO, IGCT, BJT, but also an integrated circuit made of the above active elements or/and passive elements (e.g., diodes) and control IC or other IC through co-packaging or monolithic integration.

For example, all magnetic elements of circuit 32 can be arranged in one integrated circuit module, and electronic devices other than magnetic elements of circuit 32 are arranged in another integrated circuit module. As shown in the example of FIG. 3, circuit 31 can be arranged in one integrated circuit module, and circuit 32 can be arranged in another integrated circuit module. Generally, the integrated circuit module including transformer T can be set as the main integrated circuit module (e.g., mainboard). In another example, circuit 31 can be arranged in one integrated circuit module, and circuit 32 arranged in two integrated circuit modules. For example, transformer T can be arranged in the main integrated circuit module (e.g., mainboard), and the electronic devices other than transformer T in circuit 32 may be arranged in a third integrated circuit module, such that power integrated circuit 30 includes three integrated circuit modules. Two integrated circuit modules without magnetic elements can be stacked above the integrated circuit module with magnetic elements, or two integrated circuit modules without magnetic elements can be placed above and below the integrated circuit module with magnetic elements respectively, and the three integrated circuit modules can be connected with each other, in order to form power integrated circuit 30.

It should be noted that the magnetic element welded in the main integrated circuit module can be a commercial independent inductor or transformer. The magnetic element can be an inductive element composed of some conductors in power integrated circuit 30, where the required magnetic material can be a magnetic material pre-arranged on the surface or inside or through the integrated circuit module, or a magnetic material pre-arranged around the application of power integrated circuit 30.

Therefore, in the power integrated circuit of particular embodiments, the main power stage circuit can be arranged in at least two integrated circuit modules, and at least one integrated circuit module may adopt the integrated substrate structure. The area between two adjacent intermediate metal layers can be relatively small because the intermediate metal layers in the integrated substrate are stacked up and down, and the second pads can connect to the corresponding intermediate metal layers. As such, a smaller AC loop area can be formed, thereby reducing eddy current loss. In addition, because the interconnection of some electrical networks in the power integrated circuit may have been completed inside the integrated substrate, it may only be necessary to leave a few second pads at the bottom of the integrated substrate to complete all connection with other integrated circuit modules, thus reducing the design workload of the power supply engineer at the application end. In addition, because the integrated substrate may have completed part of the electrical connection, there can be no need for external PCB to realize the part of the electrical connection, which can reduce the number of PCB layers required by the mainboard (e.g., main integrated circuit module), thus reducing the cost of the mainboard.

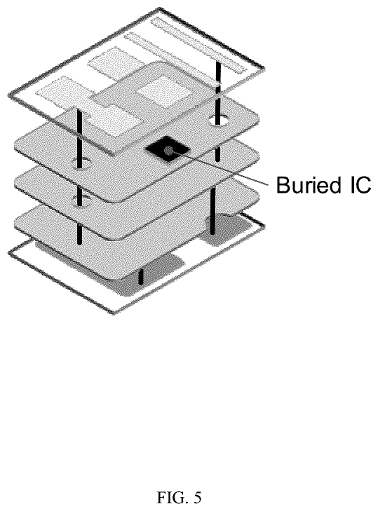

Referring now to FIG. 5, shown is a schematic structural diagram of a second example integrated substrate, in accordance with embodiments of the present invention. The IC can be embedded in the integrated substrate shown in FIG. 4 to form the integrated substrate shown in FIG. 5. Compared with the integrated substrate shown in FIG. 4, the integrated substrate shown in FIG. 5 has an additional intermediate metal layer for connecting IC. The IC can be a driver chip of power switches in the integrated circuit module, a power supply chip for driving the integrated circuit module, or other chips for realizing other functions that cooperate with the integrated circuit module. By embedding these ICs into the integrated substrate, the layout of the external circuit can be further simplified. On the other hand, because the distance between the IC and the power switch is closer, this arrangement is also helpful to reduce the AC loop area, thereby reducing the loss and parasitic inductance and improving the overall performance of the circuit.

For example, the electronic devices (including IC) arranged on the intermediate metal layer can be electrically connected with the intermediate metal layer. For example, the pins of the electronic device can be led to the same intermediate metal layer, or can be led to different regions of the same intermediate metal layer, whereby the intermediate metal layer is discontinuous and the potential of each region is not exactly the same. In another example, the pins of the electronic device can be led to different intermediate metal layers or different regions of different intermediate metal layers. Of course, it can be understood that the pins of electronic devices arranged on the intermediate metal layer may not be directly electrically connected with the intermediate metal layer, but electrically connected with the pads of the top structure or the bottom structure through the vertical penetrating connection structures.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. An integrated substrate, comprising:
a) a top structure having a plurality of first pads for mounting electronic devices, wherein each of the first pads is electrically coupled with a corresponding electronic device, such that each of the first pads has a corresponding potential;
b) a bottom structure having a plurality of second pads for coupling with peripheral circuits;
c) a plurality of intermediate metal layers stacked up and down and located between the top structure and the bottom structure;
d) a first type of penetrating connection structures configured to couple the intermediate metal layers and a part of the first pads, such that the intermediate metal layers have the same potential as the part of the first pads; and
e) a second type of penetrating connection structures configured to couple the intermediate metal layers and the second pads, such that the second pads have the same potential as the part of the first pads.

2. The integrated substrate of claim 1, wherein different first pads are coupled to the plurality of the intermediate metal layers through the plurality of the first type of penetrating connection structures respectively, such that potentials of the intermediate metal layers and the first pads are correspondingly equal.

3. The integrated substrate of claim 1, wherein the plurality of the intermediate metal layers are not in the same plane, and different intermediate metal layers respectively correspond to different potentials.

4. The integrated substrate of claim 3, wherein an adjacent two intermediate metal layers are at least partially overlapped.

5. The integrated substrate of claim 1, further comprising electronic devices arranged on the intermediate metal layers, wherein pins of the electronic devices are electrically coupled with the intermediate metal layers.

6. The integrated substrate of claim 5, wherein the intermediate metal layer has a plurality of discontinuous regions, and potentials of the plurality of discontinuous regions are not all equal.

7. The integrated substrate of claim 1, wherein insulating materials are filled between any adjacent two of the top structure, the bottom structure, and the plurality of intermediate metal layers.

8. The integrated substrate of claim 1, wherein at least one hole is opened in at least one of the top structure, the bottom structure, and the plurality of intermediate metal layers, for avoiding one or more corresponding penetrating connection structures.

9. The integrated substrate of claim 1, wherein:
a) one penetrating connection structure comprising the first type of penetrating connection structure and the second type of penetrating connection structure is configured to connect two of the top structure, the bottom structure, and the plurality of intermediate metal layers; and
b) a hole is opened in each layer between the two of the top structure, the bottom structure, and the plurality of intermediate metal layers, in order to generate a conductor-free region for avoiding the penetrating connection structure, such that the penetrating connection structure is not connected with the each layer between the two of the top structure, the bottom structure, and the plurality of intermediate metal layers.

10. The integrated substrate of claim 1, wherein:
a) one penetrating connection structure comprising the first type of penetrating connection structure and the second type of penetrating connection structure is configured to connect two of the top structure, the bottom structure, and the plurality of intermediate metal layers; and
b) a hole is opened in each layer except the two of the top structure, the bottom structure, and the plurality of intermediate metal layers, in order to generate a conductor-free region for avoiding the penetrating connection structure, such that the penetrating connection structure is not connected with the each layer except the two of the top structure, the bottom structure, and the plurality of intermediate metal layers.

11. The integrated substrate of claim 8, wherein a distance between an edge of the hole and the penetrating connection structure is greater than a predetermined threshold.

12. A power integrated circuit, comprising:
a) at least two integrated circuit modules, each having corresponding electronic devices of the power integrated circuit; and
b) wherein at least one of the integrated circuit modules comprises the integrated substrate of claim 1 to arrange electronic devices, the integrated substrate and other integrated circuit modules are stacked up and down, and the integrated circuit modules are coupled with each other to form the power integrated circuit.

13. The power integrated circuit of claim 12, wherein:
a) a part of electronic devices soldered on the integrated substrate complete partial electrical connections inside the integrated substrate according to the topology adopted by the power integrated circuit; and
b) the integrated substrate is coupled with other integrated circuit modules only through the second pads.

14. The power integrated circuit of claim 12, wherein all magnetic elements and a part of electronic devices are arranged in one integrated circuit module, and other electronic devices are arranged in another one or more integrated circuit modules.

15. The power integrated circuit of claim 12, wherein all magnetic elements are arranged in one integrated circuit module, and electronic devices are arranged in another one or more integrated circuit modules.
